(19) United States
(12) Patent Application Publication
(10) Pub. No.: US 2016/0020272 A1
(43) Pub. Date: Jan. 21, 2016

(54) Schottky Diode and Method of Manufacturing the Same

(71) Applicant: DONGBU HITEK CO., LTD., Seoul (KR)

(72) Inventor: Yong Seong KIM, Bucheon-si (KR)

(21) Appl. No.: 14/696,774

(22) Filed: Apr. 27, 2015

(30) Foreign Application Priority Data
Jul. 17, 2014 (KR) 10-2014-0090126

(51) Int. Cl. H01L 29/06; H01L 29/66; H01L 23/00; H01L 29/872

(52) U.S. Cl. CPC H01L 29/0619; H01L 29/872; H01L 29/66143; H01L 24/05; H01L 24/03; H01L 2224/02372; H01L 2924/0474

(57) ABSTRACT

A Schottky diode includes a drift region of a first conductive type formed at a surface portion of a substrate, an insulating layer disposed on the substrate and having an opening exposing a portion of the drift region, and a titanium silicide layer disposed on the portion of the drift region exposed by the opening.

### CROSS-REFERENCE TO RELATED APPLICATION

This application claims priority to Korean Patent Application No. 10-2014-0090126, filed on Jul. 17, 2014, and all the benefits accruing therefrom under 35 U.S.C. §119, the contents of which are incorporated by reference in their entirety, including the English translation thereof.

### TECHNICAL FIELD

Embodiments of the present invention relate to active solid state devices, and more particularly to devices consisting of a plurality of semiconductor or other solid state components formed in or on a common substrate, such as Schottky diodes that can be part of a larger bipolar CMOS or DMOS system.

### BACKGROUND

The present disclosure relates to a Schottky diode and a method of manufacturing the same, and more particularly, to a Schottky diode including a metal silicide layer formed on a semiconductor substrate and a method of manufacturing the same.

A Schottky diode takes advantage of the metal-semiconductor junction, which provides a Schottky barrier and is created between a metal layer and a doped semiconductor layer. For a Schottky diode with an n-type semiconductor layer, the metal layer acts as the anode, and the n-type semiconductor layer acts as the cathode. In general, the Schottky diode acts like a traditional p-n diode by readily passing current in the forward-biased direction and blocking current in the reverse-biased direction.

The Schottky diode may have a relatively low forward-biased voltage and a relatively high switching speed. However, when a sufficient reverse-biased voltage is applied to the Schottky diode, breakdown voltage and reverse-biased leakage current characteristics may deteriorate. To solve the above-mentioned problems, for example, Korean Laid-Open Patent Publication No. 10-2014-0074930 discloses a Schottky diode having reduced reverse-biased leakage currents and improved reverse-biased voltage ratings by using a Schottky layer formed of Tantalum (Ta) and a drift layer formed of silicon carbide (SiC). However, there remains a need to further improve Schottky device performance as well as reduce the cost of these devices.

### SUMMARY

The present disclosure provides a Schottky diode having improved forward-biased voltage and reverse-biased leakage current characteristics, and a method of manufacturing the same.

In accordance with an aspect of the claimed invention, a Schottky diode may include a drift region of a first conductive type formed at a surface portion of a substrate, an insulating layer disposed on the substrate and having an opening exposing a portion of the drift region, and a titanium silicide layer disposed on the portion of the drift region exposed by the opening.

In accordance with some exemplary embodiments, the Schottky diode may further include a guard ring of a second conductive type disposed under an edge portion of the titanium silicide layer.

In accordance with some exemplary embodiments, the Schottky diode may further include a landing pad disposed on the titanium silicide layer and the insulating layer, a second insulating layer disposed on the landing pad, a metal wiring disposed on the second insulating layer, and at least one via contact connecting the landing pad with the metal wiring.

In accordance with some exemplary embodiments, the Schottky diode may further include a contact pad disposed between the titanium silicide layer and the landing pad.

In accordance with some exemplary embodiments, the contact pad may extend along an upper surface of the titanium silicide layer and an inner side surface of the opening.

In accordance with some exemplary embodiments, the Schottky diode may further include a titanium layer disposed on an inner side surface of the opening and a titanium nitride layer disposed on the titanium silicide layer and the titanium layer.

In accordance with another aspect of the claimed invention, a method of manufacturing a Schottky diode may include forming a drift region of a first conductive type at a surface portion of a substrate, forming an insulating layer on the substrate, the insulating layer having an opening exposing a portion of the drift region, and forming a titanium silicide layer on the portion of the drift region exposed by the opening.

In accordance with some exemplary embodiments, the method may further include forming a guard ring of a second conductive type at a surface portion of the drift region. At this time, an inner portion of the guard ring may be exposed by the opening.

In accordance with some exemplary embodiments, the forming the titanium silicide layer may include forming a titanium layer on surfaces of the insulating layer and the drift region and heat-treating the titanium layer to form the titanium silicide layer on the portion of the drift region.

In accordance with some exemplary embodiments, the method may further include forming a titanium nitride layer on the titanium layer.

In accordance with some exemplary embodiments, the method may further include forming a landing pad on the titanium silicide layer and the insulating layer, forming a second insulating layer on the landing pad, forming at least one via contact passing through the second insulating layer, and forming a metal wiring on the second insulating layer, the metal wiring being connected with the via contact.

In accordance with some exemplary embodiments, the method may further include forming a contact pad on the titanium silicide layer. At this time, the landing pad may be electrically connected with the titanium silicide layer through the contact pad.

In accordance with some exemplary embodiments, the forming the contact pad may include forming a metal layer on surfaces of the insulating layer and the titanium silicide layer and performing a planarization process on the metal layer until an upper surface of the insulating layer is exposed to thereby obtain the contact pad in the opening.

In accordance with some exemplary embodiments, at least one contact plug connected with at least one MOS transistor on the substrate may be simultaneously formed while the contact pad is formed.

### BRIEF DESCRIPTION OF THE DRAWINGS

Exemplary embodiments can be understood in more detail from the following description taken in conjunction with the accompanying drawings, in which:

FIG. 1 is a cross-sectional view illustrating a Schottky diode in accordance with an exemplary embodiment of the claimed invention; and

FIGS. 2 to 11 are cross-sectional views illustrating a method of manufacturing the Schottky diode as shown in FIG. 1.

### DETAILED DESCRIPTION OF EMBODIMENTS

Hereinafter, specific embodiments will be described in more detail with reference to the accompanying drawings. The claimed invention may, however, be embodied in different forms and should not be construed as limited to the embodiments set forth herein.

As an explicit definition used in this application, when a layer, a film, a region or a plate is referred to as being ‘on’ another one it can be directly on the other one, or one or more intervening layers, films, regions or plates may also be present. Unlike this, it will also be understood that when a layer, a film, a region or a plate is referred to as being ‘directly on’ another one, it is directly on the other one, and one or more intervening layers, films, regions or plates do not exist. Also, though terms like a first, a second, and a third are used to describe various components, compositions, regions and layers in various embodiments of the claimed invention are not limited to these terms.

In the following description, the technical terms are used only for explaining specific embodiments while not limiting the claimed invention. Unless otherwise defined herein, all the terms used herein, which include technical or scientific terms, may have the same meaning that is generally understood by those skilled in the art.

The embodiments of the claimed invention are described with reference to schematic diagrams of ideal embodiments of the claimed invention. Accordingly, changes in the shapes of the diagrams, for example, changes in manufacturing techniques and/or allowable errors, are sufficiently expected. Accordingly, embodiments of the claimed invention are not described as being limited to specific shapes of areas described with diagrams and include deviations in the shapes and also the areas described with drawings are entirely schematic and their shapes do not represent accurate shapes and also do not limit the scope of the claimed invention.

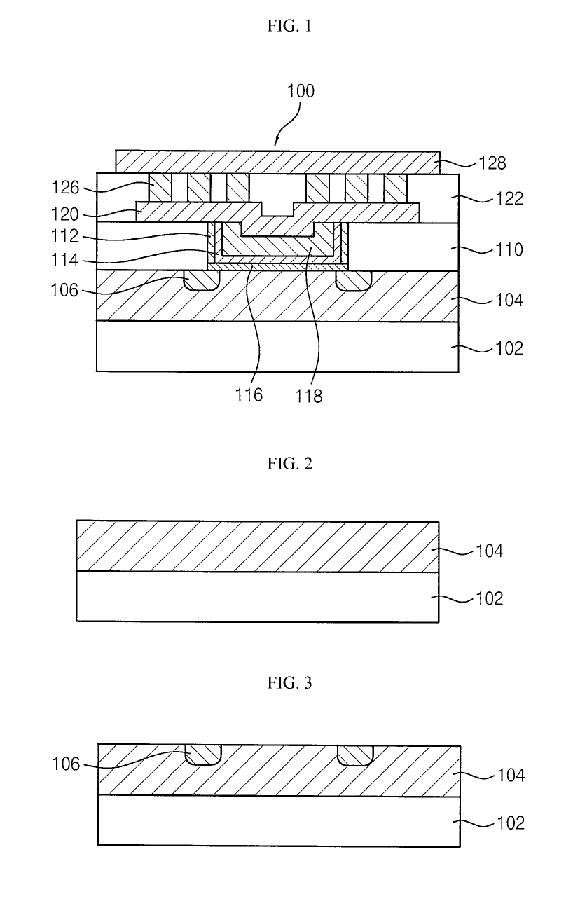

FIG. 1 is a cross-sectional view illustrating a Schottky diode in accordance with an exemplary embodiment of the claimed invention.

Referring to FIG. 1, according to an exemplary embodiment of the claimed invention, a Schottky diode 100 may be formed on a semiconductor substrate 102 such as a silicon wafer and may be used as an element of an integrated circuit device such as a Bipolar CMOS and DMOS (BCD) device.

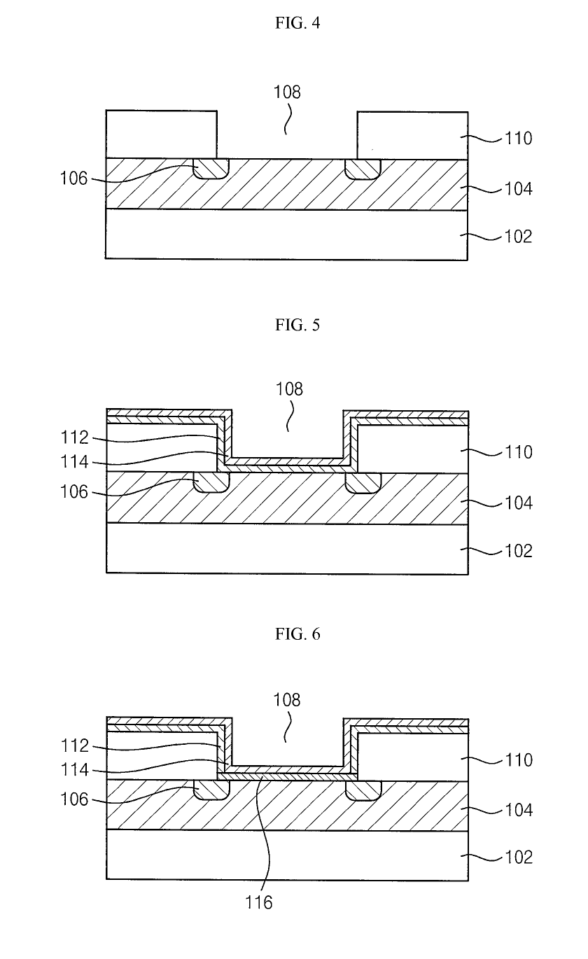

The Schottky diode 100 may include a drift region 104 of a first conductive type formed at a surface portion of the substrate 102, a first insulating layer 110 having an opening 108 (see FIG. 4) exposing a portion of the drift region 104, and a titanium silicide layer 116 formed on the portion of the drift region 104 exposed by the opening 108.

For example, the drift region 104 may be an n-type impurity region. The drift region 104 may be simultaneously formed with an n-type well region of a MOS transistor of the BCD device.

The titanium silicide layer 116 may be formed on the portion of the drift region 104 exposed at the opening 108. Particularly, the titanium silicide layer 116 may function as an anode of the Schottky diode 100, and the drift region 104 may function as a cathode of the Schottky diode 100.

The n-type drift region 104 and the titanium silicide layer 116 may relatively lower a potential barrier of the Schottky diode 100. Thus, a forward-biased voltage rating may be reduced and a forward-biased current may be increased. Further, a reverse-biased leakage current may be reduced by the n-type drift region 104 and the titanium silicide layer 116, and thus the Schottky diode 100 may have a relatively high reverse-biased voltage rating.

The Schottky diode 100 may include a guard ring 106 of a second conductive type formed under an edge portion of the titanium silicide layer 116 as shown in FIG. 1. The guard ring 106 may be used to prevent or reduce an electric field from being concentrated at a contact edge portion of the Schottky diode 100, and thus a breakdown voltage of the Schottky diode 100 may be improved. For example, a p-type impurity region may be used as the guard ring 106.

A titanium layer 112 may be disposed on an inner side surface of the opening 108, and a titanium nitride layer 114 may be disposed on the titanium silicide layer 116 and the titanium layer 112. Further, a contact pad 118 may be formed on the titanium nitride layer 114.

In accordance with an exemplary embodiment of the claimed invention, the contact pad 118 may extend along the inner side surface of the opening 108 and an upper surface of the titanium silicide layer 116 and may have a uniform thickness. For example, the contact pad 118 may be formed of tungsten and may be simultaneously formed with contact plugs of the BCD device.

The Schottky diode 100 may include a landing pad 120 electrically connected with the titanium silicide layer 116 through the contact pad 118. Further, the Schottky diode may include a second insulating layer 122 formed on the landing pad 120, a metal wiring 128 formed on the second insulating layer 122, and at least one via contact 126 passing through the second insulating layer 122 to connect the landing pad 120 with the metal wiring 128.

Particularly, the landing pad 120 may be formed on the contact pad 118 and the first insulating layer 110. That is, the landing pad 120 may have an upper surface wider than that of the titanium silicide layer 116, and the metal wiring 128 may be connected with the landing pad 120 through a plurality of via contacts 126 as shown in FIG. 1. Thus, an electric resistance between the metal wiring 128 and the titanium silicide layer 116 may be reduced. As a result, a threshold voltage of the Schottky diode 100 may be reduced and further a forward-biased current may be increased.

As shown in FIG. 1, the contact pad 118 is formed along the inner side surfaces of the opening 108 and the upper surface of the titanium silicide layer 116, and thus a recess may be formed at a central portion of the landing pad 120. In such case, the via contacts 126 may be disposed around the recess of the landing pad 120.

Meanwhile, the titanium nitride layer 114 may function as an adhesive layer between the titanium silicide layer 116 and the contact pad 118.

The landing pad 120 may be simultaneously formed with a first wiring layer of the BCD device, and the metal wiring 128 may be simultaneously formed with a second wiring layer of the BCD device. Further, the via contacts 126 may be formed by a via contact process to connect the first wiring layer with the second wiring layer of the BCD device.

FIGS. 2 to 11 are cross-sectional views illustrating a method of manufacturing the Schottky diode as shown in FIG. 1.

Referring to FIG. 2, a drift region 104 of a first conductive type may be formed at a surface portion of a substrate 102. Particularly, the drift region 104 may be an n-type impurity region and may be simultaneously formed with n-well regions (not shown) of MOS transistors of a BCD device.

For example, though not shown in figures, a first photoresist pattern (not shown) may be formed on the substrate 102 to form the drift region 104 and the n-well regions, and an ion implantation process using an n-type dopant such as arsenic and phosphorus may then be performed. The first photoresist pattern may be used as a mask during the ion implantation process for forming the drift region 104 and the n-well regions.

Referring to FIG. 3, a guard ring 106 of a second conductive type may be formed at a surface portion of the drift region 104. For example, the guard ring 106 may be a p-type impurity region and may be used to improve a breakdown voltage of a Schottky diode 100. Particularly, the guard ring 106 may be simultaneously formed with source/drain regions of PMOS transistors of the BCD device.

For example, though not shown in figures, a second photoresist pattern (not shown) may be formed on the substrate 102 to form the guard ring 106 and the source/drain regions of the PMOS transistors, and an ion implantation process using a p-type dopant such as boron and indium may then be performed. The second photoresist pattern may be used as a mask during the ion implantation process for forming the guard ring 106 and the source/drain regions of the PMOS transistors.

Referring to FIG. 4, a first insulating layer 110 having an opening 108 partially exposing the drift region 104 may be formed on the substrate 102. The first insulating layer 110 may be formed of a silicon oxide. For example, the first insulating layer 110 may be formed of a USG (undoped silica glass), a FSG (fluorinated silica glass), a BPSG (borophosphosilicate glass), and the like.

The opening 108 may expose a portion of the drift region 104 and an inner portion of the guard ring 106 as shown in FIG. 4.

The opening 108 may be simultaneously formed with contact holes (not shown) for forming contact plugs (not shown) of the BCD device. For example, a third photoresist pattern may be formed on the first insulating layer 110, and an anisotropic etching process using the third photoresist pattern as an etch mask may then be performed so as to form the opening 108 and the contact holes.

Referring to FIG. 5, a titanium layer 112 may be formed on an upper surface of the first insulating layer 110, an inner side surface of the opening 108 and an upper surface of the portion of the drift region 104 exposed by the opening 108. For example, the titanium layer 112 may be formed with a thickness of approximately 100 Å by a chemical vapor deposition (CVD) process.

Then, a titanium nitride layer 114 may be formed on the titanium layer 112. For example, the titanium nitride layer 114 may be formed with a thickness of approximately 200 Å by a chemical vapor deposition (CVD) process.

Referring to FIG. 6, after forming the titanium layer 112 and the titanium nitride layer 114, a heat-treatment process may be performed at a temperature of approximately 650° C. to approximately 750° C. so as to form a portion of the titanium layer 112 on the drift region 104 into a titanium silicide layer 116.

The titanium silicide layer 116 may function as an anode of the Schottky diode 100, and the drift region 104 under the titanium silicide layer 116 may function as a cathode of the Schottky diode 100.

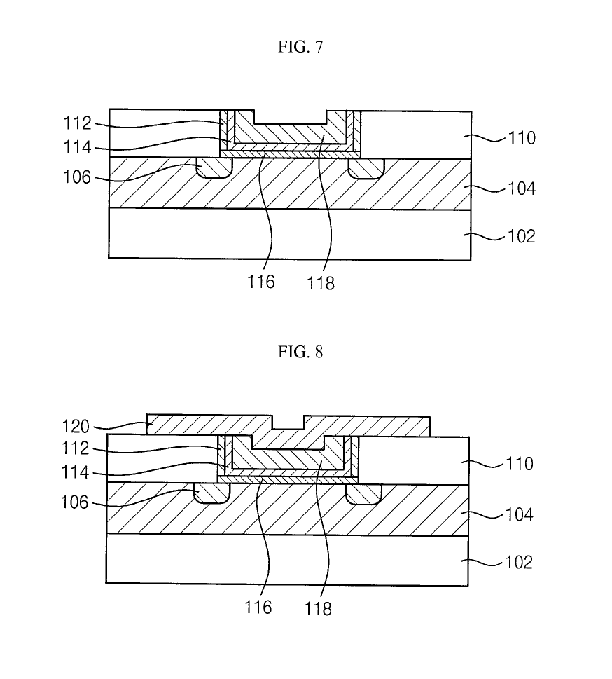

Referring to FIG. 7, a first metal layer (not shown) may be formed with a uniform thickness on the titanium nitride layer 114, and a planarization process such as a chemical mechanical polishing (CMP) process may then be performed so as to obtain a contact pad 118 in the opening 108.

For example, the first metal layer may be formed of tungsten. Further, the first metal layer may be formed with a thickness of approximately 3000 Å to approximately 4000 Å by a chemical vapor deposition (CVD) process or a physical vapor deposition (PVD) process. The planarization process may be performed until the upper surface of the first insulating layer 110 is exposed, and thus portions of the titanium layer 112, the titanium nitride layer 114, and the first metal layer on the first insulating layer 110 may be removed.

The contact pad 118 may be simultaneously formed with the contact plugs of the BCD device. Particularly, the contact holes formed in the first insulating layer 110 may be filled up with the first metal layer, and the contact plugs may be obtained by the planarization process. At this time, the titanium layer 112 and the titanium nitride layer 114 may function as an adhesive layer.

Referring to FIG. 8, a landing pad 120 may be formed on the contact pad 118 and the first insulating layer 110. For example, a second metal layer (not shown) such as an aluminum layer may be formed on the contact pad 118 and the first insulating layer 110 by a chemical vapor deposition (CVD) process or a physical vapor deposition (PVD) process, and the second metal layer may then be patterned so as to obtain the landing pad 120.

The landing pad 120 may be simultaneously formed with a first wiring layer of the BCD device. For example, a fourth photoresist pattern (not shown) may be formed on the second metal layer, and an anisotropic etching process using the fourth photoresist pattern as an etch mask may then be performed so as to obtain the landing pad 120 and the first wiring layer of the BCD device, which are connected with the contact pad 118 and the contact plugs of the BCD device, respectively.

In accordance with another exemplary embodiment of the claimed invention, the landing pad 120 may be formed by a dual damascene process. In such case, the contact pad 118 may be omitted.

Meanwhile, a second n-type impurity region (not shown) may be formed at an edge portion of the drift region 104. The second n-type impurity region may have an impurity concentration higher than that of the drift region 104. Further, a second metal wiring (not shown) may be formed on the first insulating layer 110. The second metal wiring may be connected with the second n-type impurity region by a contact plug (not shown). At this time, the second n-type impurity region may be used to electrically connect the drift region 104 with the second metal wiring.

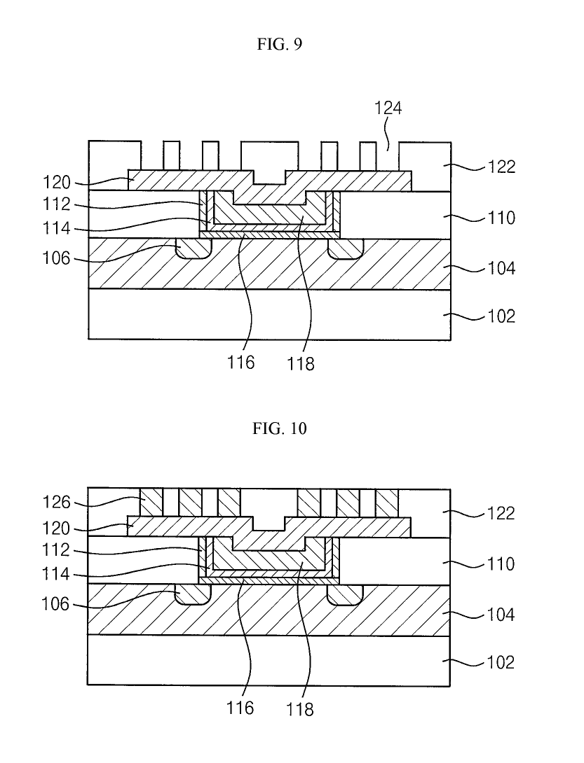

Referring FIG. 9, a second insulating layer 122 may be formed on the landing pad 120 and the first insulating layer 110. The second insulating layer 122 may be formed of a silicon oxide. For example, the second insulating layer 122 may be formed of a USG (undoped silica glass), a FSG (fluorinated silica glass), a BPSG (borophosphosilicate glass), and the like.

Then, a plurality of via holes 124 may be formed to expose the landing pad 120 in the second insulating layer 122. Particularly, via holes (not shown) for exposing the first wiring layer of the BCD device may be simultaneously formed while the depicted via holes 124 are formed.

Referring to FIG. 10, a third metal layer (not shown) may be formed to fill up the via holes 124 on the second insulating layer 122. For example, the third metal layer may include tungsten and may be formed by a chemical vapor deposition (CVD) process or a physical vapor deposition (PVD) process.

Then, a planarization process such as a chemical mechanical polishing (CMP) process may be performed until the second insulating layer 122 is exposed, and thus via contacts 126 may be obtained in the via holes 124, respectively. Meanwhile, via contacts (not shown) connected with the first wiring layer of the BCD device may be simultaneously formed with the via contacts 126.

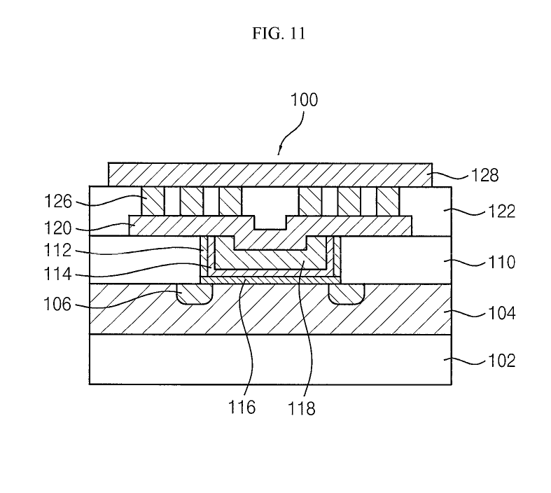

Referring to FIG. 11, a fourth metal layer (not shown) such as an aluminum layer may be formed on the second insulating layer 122 and the via contacts 126. The fourth metal layer may be patterned so as to form a metal wiring 128 electrically connected with the landing pad 120 by the via contacts 126. Meanwhile, a second wiring layer, which is electrically connected with the first wiring layer of the BCD device, may be simultaneously formed with the metal wiring 128.

In accordance with the above-mentioned embodiments of the claimed invention, a Schottky diode 100 may include an n-type drift region 104 and a titanium silicide layer 116 formed on the n-type drift region 104. A junction of the n-type drift region 104 and the titanium silicide layer 116 may provide a relatively low potential barrier. Thus, a forward-biased voltage rating and/or a threshold voltage of the Schottky diode 100 may be reduced, and a forward-biased current of the Schottky diode 100 may be increased.

Further, the junction of the n-type drift region 104 and the titanium silicide layer 116 may provide relatively high reverse-biased voltage rating and breakdown voltage, and a reverse-biased leakage current of the Schottky diode 100 may thus be reduced.

Still further, the titanium silicide layer 116 may be connected with a metal wiring 128 by using a landing pad 120 larger than the titanium silicide layer 116, and an electric resistance between the titanium silicide layer 116 and the metal wiring 128 may thus be reduced. As a result, a forward-biased voltage rating of the Schottky diode 100 may be more reduced, and further a forward-biased current of the Schottky diode 100 may be more increased.

Although the Schottky diode 100 and the method of manufacturing the same have been described with reference to the specific embodiments, they are not limited thereto. Therefore, it will be readily understood by those skilled in the art that various modifications and changes can be made thereto without departing from the spirit and scope of the claimed invention.

What is claimed is:

1. A Schottky diode comprising:
a drift region of a first conductive type formed at a surface portion of a substrate;
an insulating layer disposed on the substrate, the insulating layer having an opening exposing a portion of the drift region; and
a titanium silicide layer disposed on the portion of the drift region exposed by the opening.

2. The Schottky diode of claim 1, further comprising a guard ring of a second conductive type disposed under an edge portion of the titanium silicide layer.

3. The Schottky diode of claim 1, further comprising:
a landing pad disposed on the titanium silicide layer and the insulating layer;
a second insulating layer disposed on the landing pad;
a metal wiring disposed on the second insulating layer; and
at least one via contact connecting the landing pad with the metal wiring.

4. The Schottky diode of claim 3, further comprising a contact pad disposed between the titanium silicide layer and the landing pad.

5. The Schottky diode of claim 4, wherein the contact pad extends along an upper surface of the titanium silicide layer and an inner side surface of the opening.

6. The Schottky diode of claim 1, further comprising:
a titanium layer disposed on an inner side surface of the opening; and
a titanium nitride layer disposed on the titanium silicide layer and the titanium layer.

7. A method of manufacturing a Schottky diode, the method comprising:
forming a drift region of a first conductive type at a surface portion of a substrate;
forming an insulating layer on the substrate, the insulating layer having an opening exposing a portion of the drift region; and
forming a titanium silicide layer on the portion of the drift region exposed by the opening.

8. The method of claim 7, further comprising forming a guard ring of a second conductive type at a surface portion of the drift region, wherein an inner portion of the guard ring is exposed by the opening.

9. The method of claim 7, wherein the forming the titanium silicide layer comprises:
forming a titanium layer on surfaces of the insulating layer and the drift region; and
heat-treating the titanium layer to form the titanium silicide layer on the portion of the drift region.

10. The method of claim 9, further comprising forming a titanium nitride layer on the titanium layer.

11. The method of claim 7, further comprising:
forming a landing pad on the titanium silicide layer and the insulating layer;
forming a second insulating layer on the landing pad;
forming at least one via contact passing through the second insulating layer; and
forming a metal wiring on the second insulating layer, the metal wiring being connected with the via contact.

12. The method of claim 11, further comprising forming a contact pad on the titanium silicide layer, wherein the landing pad is electrically connected with the titanium silicide layer through the contact pad.

13. The method of claim 12, wherein the forming the contact pad comprises:
forming a metal layer on surfaces of the insulating layer and the titanium silicide layer; and
performing a planarization process on the metal layer until an upper surface of the insulating layer is exposed to thereby obtain the contact pad in the opening.

14. The method of claim 12, wherein at least one contact plug connected with at least one MOS transistor on the substrate is simultaneously formed while the contact pad is formed.
